(19) United States
(12) Patent Application Publication
(10) Pub. No.: US 2024/0353457 A1
(43) Pub. Date: Oct. 24, 2024

(54) METHOD FOR PREDICTIVE MAINTENANCE OF EQUIPMENT BY USING ANGLES TO PEAK

(71) Applicant: ITS CO., LTD., Ulju-gun, Ulsan (KR)

(72) Inventor: Young Kyu LEE, Ulsan (KR)

(21) Appl. No.: 18/685,235

(22) PCT Filed: Sep. 1, 2022
(86) PCT No.: PCT/KR2022/013118

§ 371 Date: Feb. 21, 2024

(30) Foreign Application Priority Data
Sep. 3, 2021 (KR) 10-2021-0117539

(51) Int. Cl. G01R 29/02; G01M 99/00

(52) U.S. Cl. CPC G01R 29/02; G01M 99/005

(57) ABSTRACT

Provided is a method for predictive maintenance for an apparatus, which allows inducing maintenance at an appropriate time, based on an energy waveform indicating changes over time in the energy for an operation of the apparatus in drive, by extracting a start point, an end point, and a peak point, respectively, indicating the beginning and the end of the energy waveform, and the highest energy value; detecting angles of a start point connection line and an end point connection line, each connecting the extracted points, as to a horizontal line; determining critical angles for the detected angles; comparing, with the relevant critical angles, the angles of the start point connection line and the end point connection line regarding the start, end, and the peak points, extracted from the energy waveform in real time, as to the horizontal line; and issuing a warning when abnormal symptoms in the apparatus are detected.

### TECHNICAL FIELD

The present disclosure relates to a method for predictive maintenance for an apparatus using angles associated with a peak. More specifically, the present disclosure relates to a method for predictive maintenance for an apparatus, which allows inducing maintenance or replacement for the apparatus at an appropriate time to proactively prevent considerable losses resulting from a breakdown of an apparatus, based on an energy waveform indicating changes over time in the energy required for an operation of the apparatus in drive, by extracting a start point indicating the beginning of the energy waveform, an end point indicating the end of the energy waveform, and a peak point indicating the highest energy value; detecting angles of a start point connection line and an end point connection line, each connecting the extracted points, with respect to a horizontal line; determining critical angles for the respective detected angles; comparing, with the critical angles, the angles of the start point connection line and the end point connection line regarding the start point, the end point, and the peak point, extracted from the energy waveform in real time associated with the operation of the apparatus in drive, with respect to the horizontal line; and issuing a warning when a condition raising suspicion of abnormalities in the apparatus is satisfied.

### BACKGROUND ART

In general, stable operation is very important for various apparatuses that used for automated processes of facilities.

For example, dozens or hundreds of apparatuses are installed and continuously manufacture products while operating in association with each other at a large-scale manufacturing factory. If any one of the apparatuses breaks down, a severe situation, in which the entire facility is stopped, may occur.

Such a breakdown of an apparatus causes downtime and such downtime causes a considerable loss due to not only a cost for repairing the apparatus, but also operating expenses and business effects that are wasted while the facility is stopped.

According to data from Korean Ministry of Employment and Labor and Korean Occupational Safety & Health Agency, a total of around hundred thousand people are killed or wounded every year due to industrial safety accidents and the casualties can be converted into yearly loss of 18 trillion won in expenses.

Thus, it is urgent to introduce a preventive maintenance system as a measure to avoid such unexpected downtime costs. There have been efforts to solve this problem under the name of preventive maintenance, but developing a higher level of preventive maintenance methods is necessary for more efficient preventive maintenance.

### SUMMARY

### Technical Problem

An aspect of the present disclosure, which is proposed to solve problems as described above, is to provide a method for predictive maintenance for an apparatus, which allows inducing maintenance or replacement for the apparatus at an appropriate time to proactively prevent considerable losses resulting from a breakdown of an apparatus, based on an energy waveform indicating changes over time in the energy required for an operation of the apparatus in drive, by extracting a start point indicating the beginning of the energy waveform, an end point indicating the end of the energy waveform, and a peak point indicating the highest energy value; detecting angles of a start point connection line and an end point connection line, each connecting the extracted points, with respect to a horizontal line; determining critical angles for the respective detected angles; comparing, with the critical angles, the angles of the start point connection line and the end point connection line regarding the start point, the end point, and the peak point, extracted from the energy waveform in real time associated with the operation of the apparatus in drive, with respect to the horizontal line; and issuing a warning when a condition raising suspicion of abnormalities in the apparatus is satisfied.

Another aspect of the present disclosure is to provide a method for predictive maintenance for an apparatus using angles associated with a peak, which allows a precise and effective detection of abnormalities occurring in the apparatus ensuring an excellent reliability for detected results, by proposing various detection conditions for efficiently searching for abnormal symptoms of the apparatus and detecting that the apparatus is in an abnormal state when the detection conditions are satisfied.

### Technical Solution

To this end, in an aspect, the present disclosure provides a method for predictive maintenance for an apparatus using angles associated with a peak comprising: an extraction step S10 of measuring energy waveform indicating changes over time in the energy required for an operation of the apparatus in drive and extracting a start point indicating the beginning of the energy waveform and a peak point indicating the highest energy value in the energy waveform; an information collection step S20 of forming a start point connection line connecting with a straight line the start point and the peak point, which are extracted from the energy waveform in the extraction step S10, and a horizontal line, horizontally extending from the start point and collecting massive angle information between the start point connection line and the horizontal line by repeatedly acquiring angles therebetween based on a repetitive operation of the apparatus; a setting step S30 of determining a critical angle for the angles between the start point connection line and the horizontal line based on information of angles between the start connection point and the horizontal line regarding energy waveforms, which are collected in the information collection step S20; and a detection step S40 of repeatedly collecting start points and peak points in energy waveforms regarding the repetitive operation of the apparatus in drive and, when an angle between a start point connection line, connecting a start point and a peak point which are previously collected, and the horizontal line is greater than the critical angle, issuing a warning to induce inspection management.

In addition, the critical angle in the setting step S30 is determined in a form of a range so that, when an angle between the start point connection line, connecting the start point and the peak point of the energy waveform, which are extracted in real time from the apparatus in drive, and the horizontal line is detected to be greater than a maximum angle or to be less than a minimum angle, a warning is issued.

In addition, in the extraction step S10, an end point indicating the end of the energy waveform regarding the operation of the apparatus is further extracted in addition to the start point and the peak point; in the information collection step S20, an end point connection line, connecting with a straight line the peak point and the end point, is further formed and angles between the start point connection line and the end point connection line and between the end point connection line and the horizontal line are further collected; in the setting step S30, critical angles for the angles between the start point connection line and the end point connection line and between the end point connection line and the horizontal line are further determined; and, in the detection step S40, start points, peak points, and end points are repeatedly collected from energy waveforms in real time regarding the repetitive operation of the apparatus in drive and, when at least one or two, selected from angles between a start point connection line connecting a start point and a peak point and the horizontal line, between an end point connection line connecting an end point and a peak point and a start point connection line, and between an end point connection line and the horizontal line, are greater than the relevant critical angles, a warning is issued to induce inspection management.

In addition, in the extraction step S10, an energy waveform measured regarding the operation of the apparatus is divided into a peak section including a start point and a peak point and a constant speed section, and a post peak point, indicating the highest energy value in the constant speed section, is further extracted; in the information collection step S20, a first peak point connection line, connecting with a straight line a peak point and a post peak point instead of connecting with a straight line the peak point and an end point, and a second peak point connection line, connecting with a straight line the post peak point and the end point, are further formed, and an angle between a start point connection line and the first peak point connection line, an angle between the first peak point connection line and the second peak point connection line, and an angle between the second peak point and a horizontal line are further collected; in the setting step S30, and critical angles for angles between the start point connection line and the first peak point connection line, between the first peak point connection line and the second peak point connection line, and between the second peak point and a horizontal line are respectively determined; and, in the detection step S40, start points, peak points, post peak points and end points are repeatedly collected from energy waveforms in real time regarding the repetitive operation of the apparatus in drive and, when at least one or two, selected from angles between a start point connection line connecting a start point and a peak point and the horizontal line, between a first peak point connection line connecting the peak point and a post peak point and the start point connection line, between a second peak point connection line connecting the post peak point and an end point and the first peak point connection line, and between the second peak point connection line and the horizontal line, are greater than the relevant critical angles, a warning is issued to induce inspection management.

### Effects of the Invention

According to the above described method for predictive maintenance for an apparatus using angles associated with a peak, it allows inducing maintenance or replacement for the apparatus at an appropriate time to proactively prevent considerable losses resulting from a breakdown of an apparatus, by extracting a start point indicating the beginning of the energy waveform, an end point indicating the end of the energy waveform, and a peak point indicating the highest energy value based on an energy waveform indicating changes over time in the energy required for an operation of the apparatus in drive; detecting angles of a start point connection line and an end point connection line, each connecting the extracted points, with respect to a horizontal line; determining critical angles for the respective detected angles; comparing, with the critical angles, the angles of the start point connection line and the end point connection line regarding the start point, the end point, and the peak point, extracted from the energy waveform in real time associated with the operation of the apparatus in drive, with respect to the horizontal line; and issuing a warning when a condition raising suspicion of abnormalities in the apparatus is satisfied.

In addition, the present disclosure allows a precise and effective detection of abnormalities occurring in an apparatus ensuring an excellent reliability for detected results, by proposing various detection conditions for efficiently searching for abnormal symptoms of the apparatus and detecting that the apparatus is in an abnormal state when the detection conditions are satisfied.

### BRIEF DESCRIPTION OF THE DRAWINGS

FIG. 1 is a block diagram of a method for predictive maintenance for an apparatus using angles associated with a peak according to an embodiment of the present disclosure.

FIG. 2 to FIG. 8 are diagrams for illustrating a method for predictive maintenance for an apparatus using angles associated with a peak shown in FIG. 1.

### DETAILED DESCRIPTIONS OF EXEMPLARY EMBODIMENTS

Hereinafter, a method for predictive maintenance for an apparatus using angles associated with a peak according to a preferred embodiment of the present disclosure will be described in detail with reference to the accompanying drawings. In describing the present disclosure, a detailed description of a well-known configuration or function related the present disclosure, which may obscure the subject matter of the present disclosure, will be omitted.

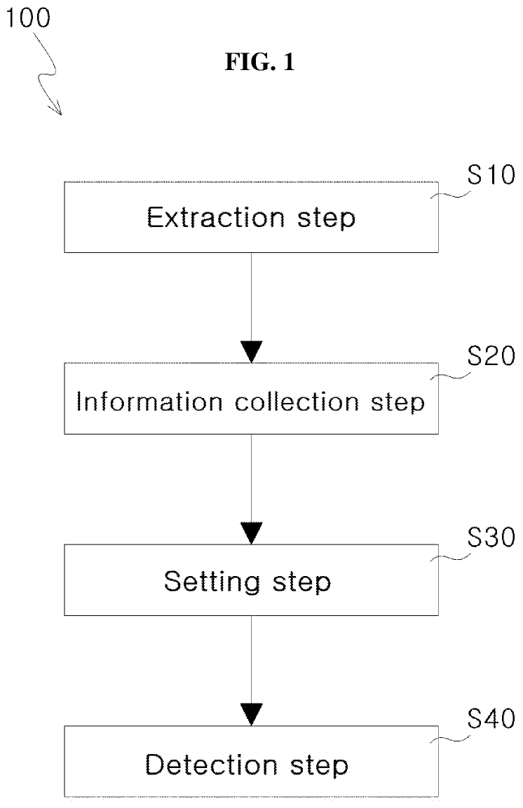

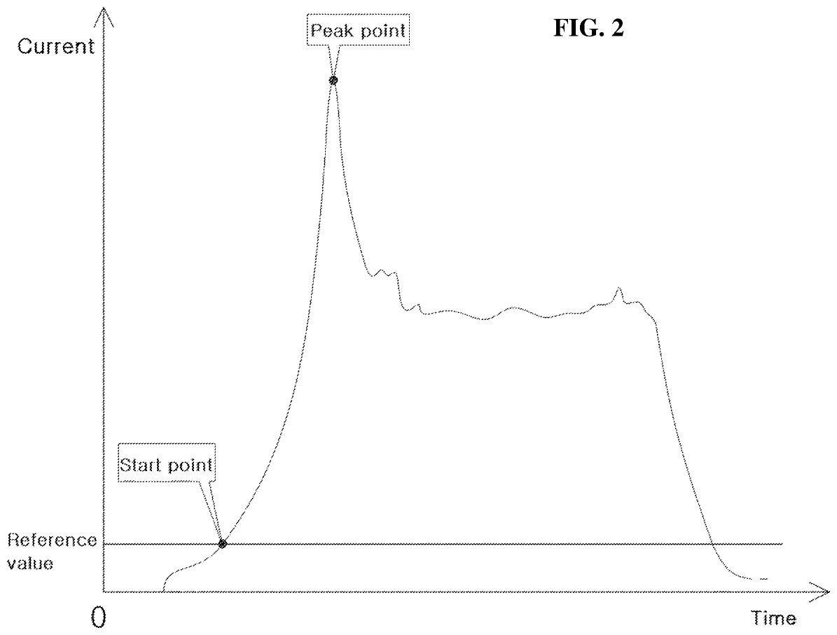

FIG. 1 to FIG. 8 illustrate a method for predictive maintenance for an apparatus using angles associated with a peak according to an embodiment of the present disclosure, wherein FIG. 1 is a block diagram of a method for predictive maintenance for an apparatus using angles associated with a peak according to an embodiment of the present disclosure and FIG. 2 to FIG. 8 are diagrams respectively for illustrating a method for predictive maintenance for an apparatus using angles associated with a peak shown in FIG. 1.

As shown in FIG. 1, a method for predictive maintenance 100 for an apparatus using angles associated with a peak according to an embodiment of the present disclosure comprises an extraction step S10, an information collection step S20, a setting step S30, and a detection step S40.

### MODE FOR IMPLEMENTING THE INVENTION

The extraction step S10 is a process of measuring energy waveforms indicating changes over time in the energy required for an operation of an apparatus in drive and extracting a start point indicating the beginning of the measured energy waveform and a peak point indicating the highest energy value in the energy waveform.

Typically, an apparatus which is installed in a large facility and organically performs, repeatedly performs a specific operation. Here, energy required for the operation of the apparatus may be verified by selectively using a current (power), a frequency of supplied power, vibrations, noise generated from the apparatus, etc.

For example, in the case of an apparatus, such as a welder, performing an operation like welding on a basic material, if a current supplied to the apparatus is represented as energy required for performing the operation, a waveform as shown in FIG. 2 may be obtained.

Here, the peak point indicates the highest energy value in the energy waveform and the start point indicates the beginning of the waveform. However, typically, even when one operation of an apparatus is completed, the apparatus is not completely stopped, but stands by for repeating the operation, and thus, a low current is maintained in the apparatus. For this reason, in order to obtain a clear start point from repetitive waveforms, it is preferable to determine a reference value and to take a point where an waveform rises up to be equal to or higher than this reference value as a start point.

The information collection step S20 is a process of forming a start point connection line connecting with a straight line the start point and the peak point, which are extracted from the energy waveform in the extraction step S10, and a horizontal line horizontally extending from the start point, and collecting massive angle information between the start point connection line and the horizontal line by repeatedly acquiring angles therebetween based on the repetitive operation.

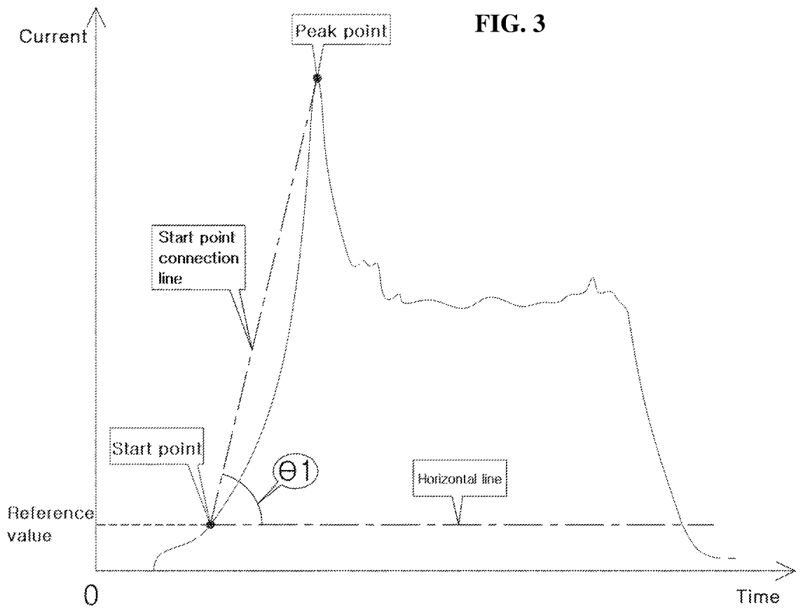

That is, as shown in FIG. 3, information of an angle θ1 between the start point connection line and the horizontal line regarding the energy waveform is repeatedly collected. Such collected angle information becomes a basis of determining a critical angle for the angle between the start point connection line and the horizontal line in the setting step S30 to be described below.

Although internal angles (acute angles) between the start point connection line and the horizontal line are measured and collected in the information collection step S20 for the convenience of descriptions, it is certainly possible to measure and collect external angles.

The setting step S30 is a step of setting a critical angle for angles between the start point connection line and the horizontal line based on information of angles between the start point connection line and the horizontal line collected in the information collection step S20.

Here, the critical angle for the angles between the start point connection line and the horizontal line, which is to issue a warning when the peak point is abnormally changed in the energy waveform for the apparatus, is determined in a form of a range.

In the detection step S40, when an angle, between the start point connection line connecting the start point and the peak point in the energy waveform extracted in real time regarding the apparatus in drive and the horizontal line, is detected to be greater than the maximum of the critical angle or to be less than the minimum of the critical angle, a warning is issued.

Here, the reason why the critical angle for angles between the start point connection line and the horizontal line is set in a form of a certain range (from the maximum angle to the minimum angle) is to appropriately detect various cases in which the apparatus may be considered to be in an abnormal state like a case in which the peak point is too high or too low in the energy waveform for the apparatus or a case in which the peak point is formed too early or too late.

It is evident that the critical angle for angles between the start point connection line and the horizontal line may be defined within various ranges, taking into account the type, usage environment, life of an apparatus, etc.

The detection step S40 is a step of repeatedly collecting start points and peak points from energy waveforms in real time regarding the repetitive operation of the apparatus in drive and, when an angle, between the start point connection line connecting the start point and the peak point and the horizontal line, is greater than the critical angle, issuing a warning to induce the inspection management of the apparatus.

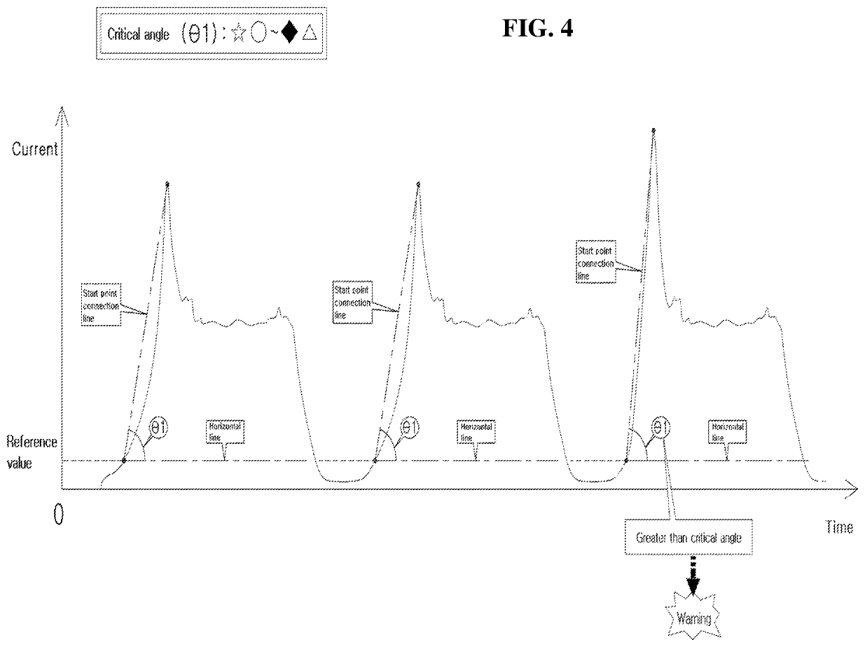

That is, as shown in FIG. 4, when the angle, between the start point connection line connecting the start point and the peak point of the energy waveform in real time regarding the repetitive operation of the apparatus in drive and the horizontal line, is not greater than the critical angle set in the setting step S30, the apparatus is detected to be in a stable state. On the contrary, when the angle, between the start point connection line connecting the start point and the peak point of the energy waveform in real time and the horizontal line, is greater than the critical angle, the apparatus is detected to be in a somewhat unstable state and a warning is issued. In this way, abnormal symptoms of an apparatus may be detected before any breakdown occurs so that the inspection and management of the apparatus can be induced. This allows proactive prevention of economic losses that may result from an entire shutdown of a facility due to a sudden breakdown of the apparatus.

Meanwhile, in the extraction step S10, an end point, indicating the end of an energy waveform regarding an operation of the apparatus, is further extracted in addition to the start point and the peak point.

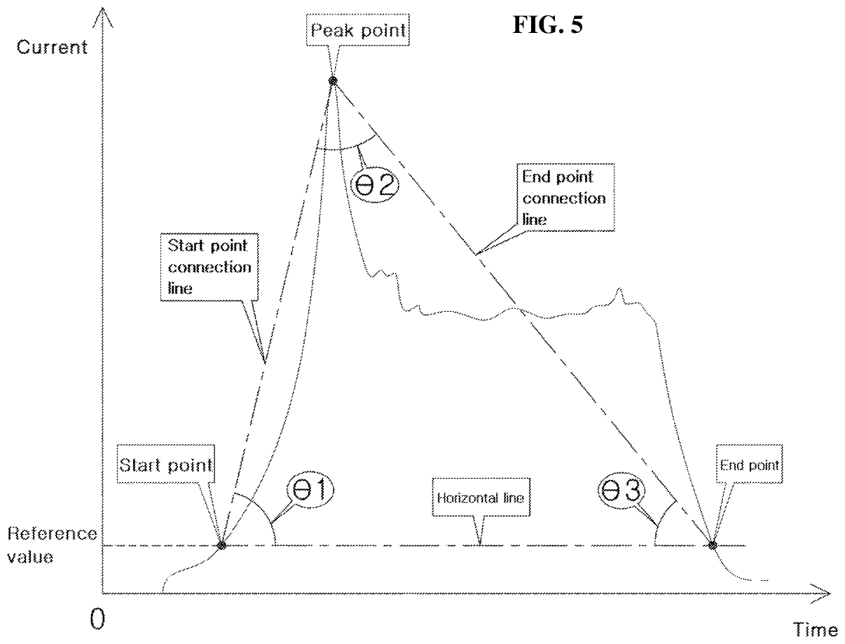

That is, as shown in FIG. 5, an exact end point is obtained from an energy waveform regarding an operation by defining a point, where the energy waveform passes the reference value after the energy waveform has exceeded the reference value, as an end point.

Then, in the information collecting step S20, an end point connection line connecting the peak point and the end point with a straight line is formed and information of an angle between the start point connection line and the end point connection line and an angle between the end point connection line and the horizontal line is further collected.

That is, as shown in FIG. 5, using the end point extracted from the energy waveform, information of an angle θ2 between the start point connection line and the end point connection line and an angle θ3 between the end point connection line and the horizontal line is further collected and such collected angle information becomes a basis of determining critical angles for the angle θ2 between the start point connection line and the end point connection line and the angle θ3 between the end point connection line and the horizontal line in the setting step S30.

In the setting step S30, critical angles respectively for the angle between the start point connection line and the end point connection line and the angle between the end point connection line and the horizontal line are further determined.

Here, each of the critical angles for the angle between the start point connection line and the end point connection line and the angle between the end point connection line and the horizontal line may be determined in a form of a range.

In the detection step S40, start points, peak points, and end points are repeatedly collected from energy waveforms in real time regarding the repetitive operation of the apparatus in drive and, when at least one or two, selected from the angle between the start point connection line connecting a start point and a peak point and the horizontal line, the angle between the end point connection line connecting the peak point and an end point and the start point connection line, and the angle between the end point connection line and the horizontal line, are greater than the relevant critical angles, a warning is issued to induce the inspection management of the apparatus.

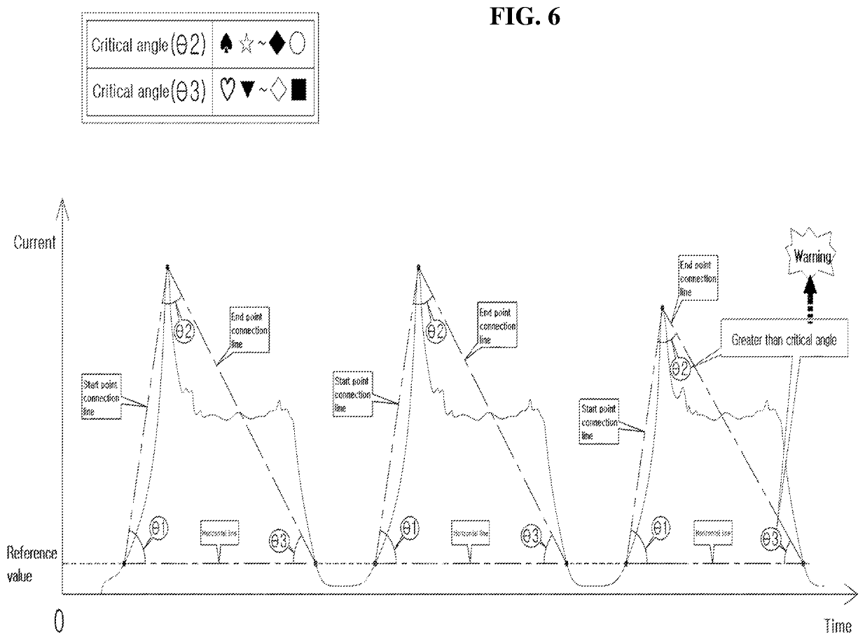

That is, as shown in FIG. 6, based on the start points, the peak points, and the end points of the energy waveform regarding the repetitive operation of the apparatus in drive, when at least one or two, selected from the angle between the start point connection line and the horizontal line, the angle between the end point connection line and the start point connection line, and the angle between the end point connection line and the horizontal line, are not greater than the relevant critical angles, the apparatus is detected to be in a stable state. On the contrary, when the at least one or two angles are greater than the relevant critical angles, the apparatus is detected to be in a somewhat unstable state and a warning is issued. In this way, abnormal symptoms of an apparatus may be detected before any breakdown occurs so that the inspection and management of the apparatus can be induced. This allows proactive prevention of economic losses that may result from an entire shutdown of a facility due to a sudden breakdown of the apparatus.

FIG. 6 illustrates an example in which a real time state of the apparatus is detected by selectively measuring the angle between the end point connection line and the start point connection line and the angle between the end point connection line and the horizontal line and comparing the angles with the relevant critical angles.

Meanwhile, in the extraction step S10, the energy waveform measured regarding the operation of the apparatus is divided into a peak section including a start point and a peak point and a constant speed section, and a post peak point, indicating the highest energy value in the constant speed section, is further extracted.

Here, the peak section means a section where a high current consumption is indicated in the energy waveform regarding the apparatus and the constant speed section means a section where consumption of the current is constantly maintained in the energy waveform.

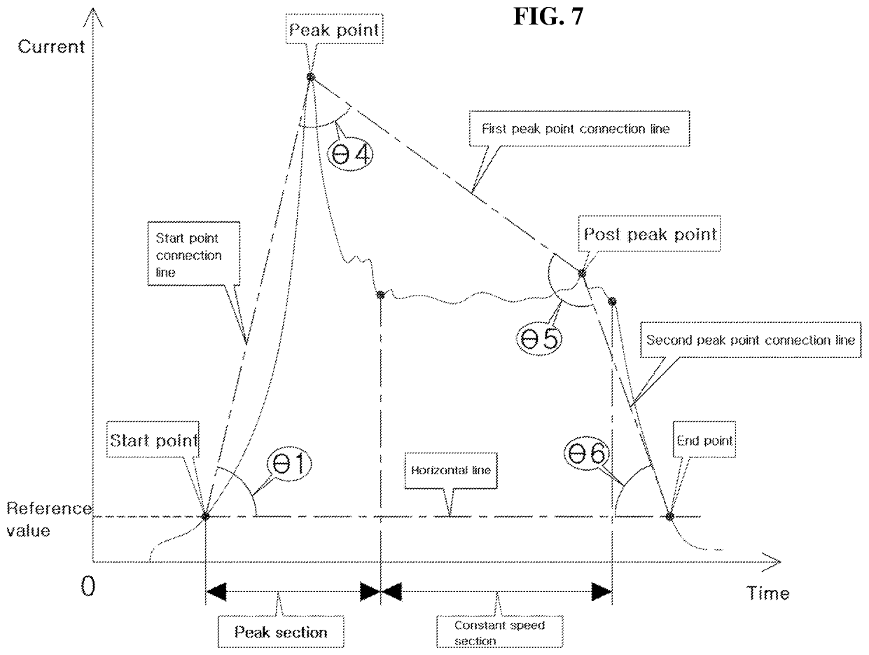

That is, as shown in FIG. 7, a point indicating the highest energy value in the constant speed section of the energy waveform regarding the apparatus is taken as a post peak point and post peak points are repeatedly collected from the energy waveform regarding the operation in addition to the start point, the peak point, and the end point.

In the information collection step S20, instead of the end point connection line connecting the peak point and the end point with a straight line, a first peak point connection line connecting the peak point and the post peak point with a straight line and a second peak point connection line connecting the post peak point and the end point with a straight line are further formed, and an angle between the start point connection line and the first peak point connection line, an angle between the first peak point connection line and the second peak point connection line, and an angle between the second peak point connection line and the horizontal line are further collected.

That is, as shown in FIG. 7, using the post peak point further extracted from the energy waveform, information of the angle θ4 between the start point connection line and the first peak point connection line, the angle θ5 between the first peak point connection line and the second peak point connection line, and the angle θ6 between the second peak point connection line and the horizontal line is further collected together with the angle θ1 between the horizontal line and the start point connection line. Such collected angle information becomes a basis of determining critical angles respectively for the angle θ4 between the start point connection line and the first peak point connection line, the angle θ5 between the first peak point connection line and the second peak point connection line, and the angle θ6 between the second peak point connection line and the horizontal line in the setting step S30.

In the setting step S30, critical angles respectively for the angle between the start point connection line and the first peak point connection line, the angle between the first peak point connection line and the second peak point connection line, and the angle between the second peak point connection line and the horizontal line are further determined.

Here, each of the critical angles for the angle between the start point connection line and the first peak point connection line, the angle between the first peak point connection line and the second peak point connection line, and the angle between the second peak point connection line and the horizontal line may be determined in a form of ranges.

In the detection step S40, start points, peak points, post peak points, and end points are repeatedly collected from energy waveforms in real time regarding the repetitive operation of the apparatus in drive and, when at least one or two, selected from the angle between the start point connection line connecting a start point and a peak point and the horizontal line, the angle between the first peak point connection line connecting the peak point and a post peak point and the start point connection line, the angle between the second peak point connection line connecting the peak point and the post peak point and the start point connection line, and the angle between the second peak point connection line and the horizontal line, are greater than the relevant critical angles, a warning is issued to induce the inspection management of the apparatus.

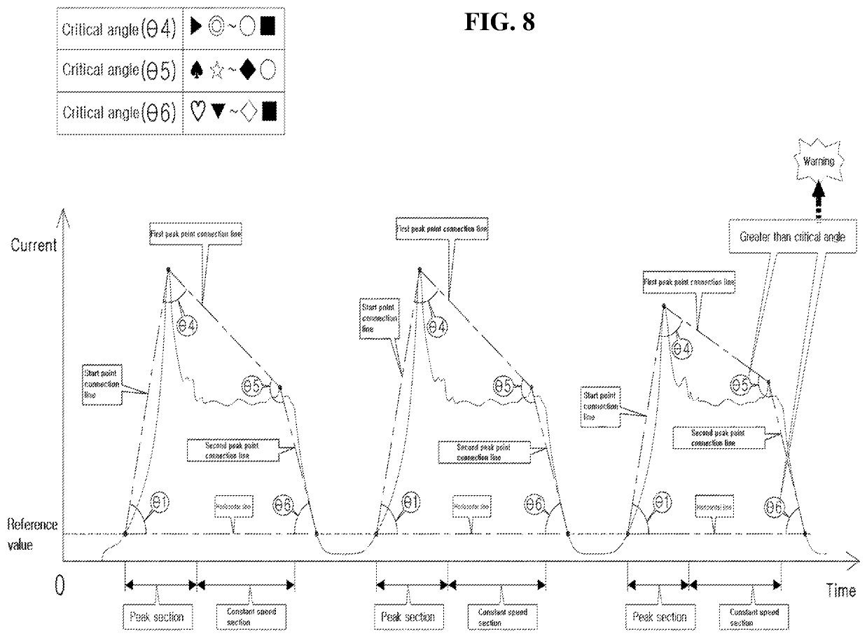

That is, as shown in FIG. 8, based on the start points, the peak points, the post peak points, and the end points of the energy waveforms regarding a repetitive operation of the apparatus in drive, when at least one or two, selected from the angle between the start point connection line and the horizontal line, the angle between the start point connection line and the first peak point connection line, the angle between the first peak point connection line and the second peak point connection line, and the angle between the second peak point connection line and the horizontal line, are not greater than the relevant critical angles, the apparatus is detected to be in a stable state. On the contrary, when the at least one or two angles are greater than the relevant critical angles, the apparatus is detected to be in a somewhat unstable state and a warning is issued. In this way, abnormal symptoms of an apparatus may be detected before any breakdown occurs so that the inspection and management of the apparatus can be induced. This allows proactive prevention of economic losses that may result from an entire shutdown of a facility due to a sudden breakdown of the apparatus.

FIG. 8 illustrates an example in which a real time state of the apparatus is detected by selectively measuring the angle between the start point connection line and the first peak point connection line, the angle between the first peak point connection line and the second peak point connection line, and the angle between the second peak point connection line and the horizontal line and comparing the angles with the relevant critical angles.

In this way, the method for predictive maintenance for an apparatus using angles associated with a peak allows inducing maintenance or replacement for the apparatus at an appropriate time to proactively prevent considerable losses resulting from a breakdown of an apparatus, based on an energy waveform indicating changes over time in the energy required for an operation of the apparatus in drive, by extracting a start point indicating the beginning of the energy waveform, an end point indicating the end of the energy waveform, and a peak point indicating the highest energy value; detecting angles of a start point connection line and an end point connection line, each connecting the extracted points, with respect to a horizontal line; determining critical angles for the respective detected angles; comparing with the relevant critical angles the angles with respect to the start point connection line, the end point connection line, and the horizontal line associated with the start point, the end point, and the peak point, extracted from the energy waveform in real time regarding the operation of the apparatus in drive; and issuing a warning when a condition raising suspicion of abnormalities in the apparatus is satisfied.

In addition, the present disclosure allows a precise and effective detection of abnormal symptoms occurring in the apparatus ensuring an excellent reliability for detected results, by proposing various detection conditions for efficiently searching for abnormal symptoms of the apparatus and by detecting that the apparatus is in an abnormal state when the detection conditions are satisfied.

It is evident that the method 100 for predictive maintenance using angles associated with a peak according to the present disclosure may be implemented by combinations of various electronic apparatuses and programs, which allow the collection, detection, and comparison of energy waveforms of an apparatus and issuing a warning.

Although the embodiments of the present disclosure are described with reference to the drawings, a person with ordinary skill in the art, to which the present disclosure pertains, would understand that the present disclosure is not limited to the above embodiments described as examples and various modifications and equivalent embodiments are possible. In addition, it is evident that modifications may be made by a person skilled in the art without departing from the idea of the present disclosure. Therefore, the scope for which a right is claimed in the present disclosure should be understood not to be restricted solely to the detailed description but, rather, it is delimited by the claims provided below and the underlying technical idea.

### INDUSTRIAL APPLICABILITY

The present disclosure is applicable to the industry of predictive maintenance for apparatuses.

1. A method for predictive maintenance for an apparatus using angles associated with a peak, which may be used for various facilities, comprising:
an extraction step S10 of measuring energy waveform indicating changes over time in the energy required for an operation of the apparatus in drive and extracting a start point indicating the beginning of the energy waveform and a peak point indicating the highest energy value in the energy waveform;
an information collection step S20 of forming a start point connection line connecting, with a straight line, the start point and the peak point, which are extracted from the energy waveform in the extraction step S10, and a horizontal line, horizontally extending from the start point and collecting massive angle information between the start point connection line and the horizontal line by repeatedly acquiring angles therebetween based on a repetitive operation;
a setting step S30 of determining a critical angle for the angles between the start point connection line and the horizontal line based on information of angles between the start connection point line and the horizontal line regarding energy waveforms, which is collected in the information collection step S20; and
a detection step S40 of repeatedly collecting start points and peak points in energy waveforms in real time regarding the repetitive operation of the apparatus in drive and, when an angle between a start point connection line, connecting a start point and a peak point which are previously collected, and the horizontal line is greater than the critical angle, issuing a warning to induce inspection management.

2. The method for predictive maintenance of claim 1, wherein the critical angle in the setting step S30 is determined in a form of a range so that, when an angle between a start point connection line, connecting a start point and a peak point of an energy waveform, which are extracted in real time from the apparatus in drive, and the horizontal line is detected to be greater a maximum angle or to be less than a minimum angle, a warning is issued.

3. The method for predictive maintenance of claim 1, wherein
in the extraction step S10, an end point indicating the end of an energy waveform regarding the operation of the apparatus is further extracted in addition to the start point and the peak point;
in the information collection step S20, an end point connection line, connecting with a straight line the peak point and the end point, is further formed and angles between the start point connection line and the end point connection line and between the end point connection line and the horizontal line are further collected;
in the setting step S30, critical angles for the angles between the start point connection line and the end point connection line and between the end point connection line and the horizontal line are further determined; and
in the detection step S40, start points, peak points, and end points are repeatedly collected from energy waveforms in real time regarding the repetitive operation of the apparatus in drive and, when at least one or two, selected from angles between a start point connection line connecting a start point and a peak point and the horizontal line, between an end point connection line connecting an end point and the peak point and the start point connection line, and between the end point connection line and the horizontal line, are greater than the relevant critical angles, a warning is issued to induce inspection management.

4. The method for predictive maintenance of claim 3, wherein,
in the extraction step S10, the energy waveform measured regarding the operation of the apparatus is divided into a peak section including a start point and a peak point and a constant speed section, and a post peak point, indicating the highest energy value in the constant speed section, is further extracted;
in the information collection step S20, a first peak point connection line, connecting with a straight line a peak point and the post peak point instead of the end point connection line connecting with a straight line the peak point and the end point, and a second peak point connection line, connecting with a straight line the post peak point and the end point, are further formed, and information of an angle between the start point connection line and the first peak point connection line, an angle between the first peak point connection line and the second peak point connection line, and an angle between the second peak point and the horizontal line is further collected;
in the setting step S30, critical angles for the angle between the start point connection line and the first peak point connection line, the angle between the first peak point connection line and the second peak point connection line, and the angle between the second peak point and the horizontal line are respectively determined; and
in the detection step S40, start points, peak points, post peak points, and end points are repeatedly collected from energy waveforms in real time regarding the repetitive operation of the apparatus in drive and, when at least one or two, selected from angles between a start point connection line connecting a start point and a peak point and the horizontal line, between a first peak point connection line connecting the peak point and a post peak point and the start point connection line, between a second peak point connection line connecting the post peak point and an end point and the first peak point connection line, and between the second peak point connection line and the horizontal line, are greater than the relevant critical angles, a warning is issued to induce inspection management.
